(19) United States
(12) Patent Application Publication
(10) Pub. No.: US 2025/0098132 A1
(43) Pub. Date: Mar. 20, 2025

(54) REEL HOLDING DEVICE AND TAPE FEEDER

(71) Applicant: FUJI CORPORATION, Chiryu (JP)

(72) Inventor: Hiroki MURASE, Nagoya-shi (JP)

(73) Assignee: FUJI CORPORATION, Chiryu (JP)

(21) Appl. No.: 18/728,907

(22) PCT Filed: Mar. 4, 2022
(86) PCT No.: PCT/JP2022/009394

§ 371 Date: Jul. 15, 2024

(51) Int. Cl. H05K 13/02; H05K 13/04

(52) U.S. Cl. CPC H05K 13/02; H05K 13/0419

(57) ABSTRACT

A reel holding device includes a main body, a pressing plate openable and closable with respect to the main body to press a side surface orthogonal to a central axis of a reel around which a component supply tape is wound and which is accommodated in a reel holder, and a holding section configured to attract and hold the pressing plate by a magnetic force in a closed state in which the pressing plate presses the reel, in which the holding section includes an attracting portion configured to attract the pressing plate and a peripheral portion adjacent to the attracting portion, and a magnetic force larger than a magnetic force of the attracting portion is generated in at least a part of the peripheral portion.

### TECHNICAL FIELD

The present description relates to a reel holding device and a tape feeder.

### BACKGROUND ART

Conventionally, for example, a reel holding device disclosed in the following Patent Literature 1 has been disclosed. In a conventional reel holding device, a movement limiting member that presses a side surface of a reel is provided on a reel holding side surface of a slide body. A first end of the movement limiting member is supported by a pin member to be rotatable, and a magnetic body is attached to a second end thereof. When the movement limiting member rotates about the pin member, the magnetic body at the second end of the movement limiting member is attracted by the magnet provided at a distal end of a center pin and is coupled to the center pin.

### PATENT LITERATURE

Patent Literature 1: JP-A-2020-102561

### SUMMARY OF THE INVENTION

### Technical Problem

At this time, when a work of mounting a reel on a reel holding device is performed, a component may be dropped unintentionally from a component supply tape wound on the reel. In the above-described conventional reel holding device, the dropped component may be attracted by the magnet provided at the distal end of the center pin. When the component is attracted by the distal end of the center pin, the component is engaged between the movement limiting member and the center pin, so that the movement limiting member spreads outward and the width of the slide body becomes larger. As a result, when the slide body is set on the slide support portion, the slide body may interfere with another adjacent slide body.

An object of the present description is to provide a reel holding device and a tape feeder that suppress expansion in a width direction when a reel is mounted.

### Solution to Problem

The present description discloses a reel holding device including: a main body; a pressing plate openable and closable with respect to the main body to press a side surface orthogonal to a central axis of a reel around which a component supply tape is wound and which is accommodated in a reel holder; and a holding section configured to attract and hold the pressing plate by a magnetic force in a closed state in which the pressing plate presses the reel, in which the holding section includes an attracting portion configured to attract the pressing plate and a peripheral portion adjacent to the attracting portion, and a magnetic force larger than a magnetic force of the attracting portion is generated in at least a part of the peripheral portion.

With the reel holding device, in a case where the component is dropped unintentionally from the component supply tape in a work of mounting the reel, the holding section can preferentially attract the component at the peripheral portion having a large magnetic force. In other words, it is possible to reduce the possibility (or frequency) that the attracting portion that is adjacent to the peripheral portion and attracts the pressing plate attracts the component. Accordingly, when the attracting portion of the holding section attracts and holds the pressing plate, it is possible to suppress the component that has been dropped and attracted from being present (being engaged) between the attracting portion and the pressing plate. Thereby, it is possible to suppress spreading of the reel holding device in a width direction due to the opening of the pressing plate when the reel is mounted, and it is possible to prevent interference with another adjacent device.

### BRIEF DESCRIPTION OF DRAWINGS

FIG. 1 is a view illustrating a production system including multiple component mounters.

FIG. 2 is a view schematically illustrating an overall configuration of the component mounter in FIG. 1.

FIG. 3 is a side view schematically illustrating a main part of a tape feeder of FIG. 1.

FIG. 4 is a top view schematically illustrating a component supply tape.

FIG. 5 is an enlarged view illustrating a holding section and a magnet in FIG. 3.

FIG. 6 is a view illustrating attracting of a component by the holding section in FIG. 5.

FIG. 7 is a view illustrating engagement of the component.

FIG. 8 is an enlarged view illustrating a holding section of a first modification example.

FIG. 9 is an enlarged view illustrating a holding section of a second modification example.

### DESCRIPTION OF EMBODIMENTS

Hereinafter, a reel holding device and a tape feeder including the reel holding device will be described with reference to the drawings. In the present embodiment, a production system in which a tape feeder is conveyed to a component mounter by an automatic conveyance machine will be described as an example.

### 1. Overall Configuration of Production System 10

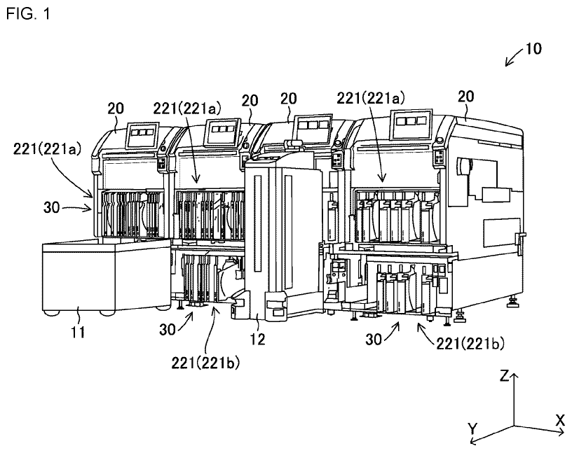

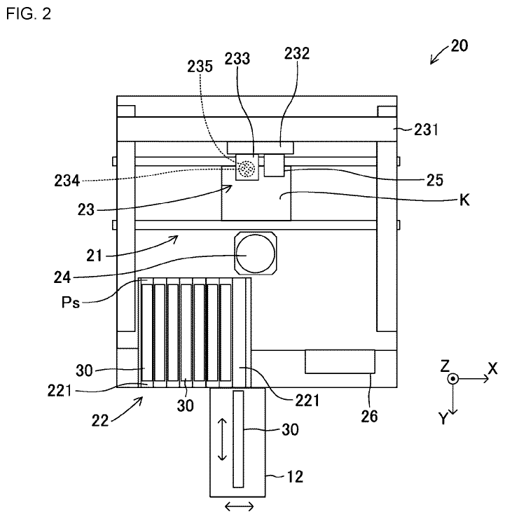

As illustrated in FIG. 1, production system 10 includes multiple component mounters 20 arranged in a width direction. Component mounter 20 is a board work machine that performs a mounting operation of mounting component P (for example, an electronic component) on circuit board K (refer to FIG. 2) as a predetermined work. In production system 10 formed by multiple component mounters 20, circuit boards K are subsequently conveyed into respective component mounters 20, and predetermined components are mounted in respective component mounters 20.

Here, in the present embodiment, only component mounter 20 is exemplified as the board work machine. However, it is also possible to form production system 10 by including other devices such as a printing machine, an inspection machine, and a reflow oven as a board work machine.

In the present embodiment, a case where production system 10 is formed by multiple component mounters 20 is exemplified. However, it is needless to say that one (single) component mounter 20 can be provided and performed without forming a production system. In the following description, an X-axis direction is a left-right direction (width direction) of component mounter 20, a Y-axis direction is a front-rear direction (depth direction) of component mounter 20, and a Z-axis direction is an up-down direction (vertical direction) of component mounter 20.

In addition, production system 10 includes automatic conveyance machine 11 that conveys and attaches and detaches tape feeder 30, which will be described later, to and from each of component mounters 20. Here, examples of automatic conveyance machine 11 include an automatic guided vehicle (AGV) that is an unmanned conveyance vehicle (unmanned conveyance robot) that automatically reciprocates between an automatic warehouse (not illustrated) and component mounter 20 to convey predetermined tape feeder 30. Although not illustrated, automatic conveyance machine 11 includes an attaching and detaching mechanism (for example, a belt conveyor, an articulated robot, or the like) for attaching and detaching tape feeder 30 to and from component supply device 22 of component mounter 20 described later.

Production system 10 further includes loader 12 that performs replenishment of components P and a setup change for the next production in accordance with a production schedule. Loader 12 is disposed in front of component mounter 20 (more specifically, component supply device 22 described later) in the Y-axis direction and is movable in the X-axis direction (refer to FIG. 2). Further, loader 12 moves tape feeder 30 from upper stage 221a to lower stage 221b or from lower stage 221b to upper stage 221a in slot 221 of component supply device 22 described later.

Specifically, loader 12 can temporarily accommodate (collect) tape feeder 30 set in upper stage 221a of slot 221, move in the X-axis direction, and then discharge and set accommodated (collected) tape feeder 30 to lower stage 221b. Loader 12 can temporarily accommodate (collect) tape feeder 30 set in lower stage 221b of slot 221, move in the X-axis direction, and then discharge and set accommodated (collected) tape feeder 30 to upper stage 221a. Accordingly, loader 12 can automatically perform the supply and the setup change of component P. In the present embodiment, loader 12 is movable in the X-axis direction across adjacent component mounter 20 (component supply device 22).

In production system 10, a control device (not illustrated) for controlling production is provided in addition to the above-described devices. The control device may be, for example, a host computer, a buffer, or the like communicably connected to the board work machine.

### 2. Component Mounter 20

As schematically illustrated in FIG. 2, component mounter 20 mainly includes board conveyance device 21, component supply device 22, component transfer device 23, part camera 24, board camera 25, and control device 26.

Board conveyance device 21 is configured with a belt conveyor or the like, and subsequently conveys circuit board K in the X-axis direction. Board conveyance device 21 positions circuit board K at a predetermined position inside component mounter 20. When a mounting operation on positioned circuit board K is completed, board conveyance device 21 carries out circuit board K to the outside of component mounter 20 (for example, the adjacent component mounter 20).

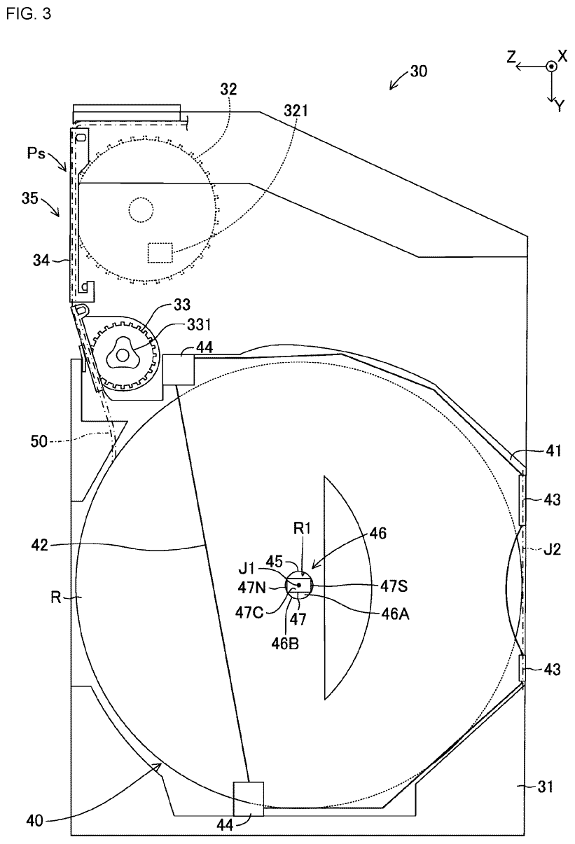

Component supply device 22 supplies components P (for example, electronic components) to be mounted on circuit board K. Component supply device 22 includes multiple slots 221 arranged in the X-axis direction, and tape feeder 30 is detachably set in each slot 221. Here, slot 221 of the present embodiment is formed by upper stage 221a and lower stage 221b along the Z-axis direction (refer to FIG. 1). Component supply device 22 feeds and moves component supply tape 50 that supplies component P to be described later by tape feeder 30, and supplies component P to component supply position Ps (refer to FIG. 3) provided on the distal end side (upper side in FIG. 2) of tape feeder 30.

Component transfer device 23 holds component P supplied to component supply position Ps, and mounts held component P on positioned circuit board K. Component transfer device 23 mainly includes head driving device 231, moving table 232, and mounting head 233. Head driving device 231 moves moving table 232 in the X-axis direction and the Y-axis direction by a linear motion mechanism.

Mounting head 233 is a holding device that holds component P, and is detachably provided on moving table 232. In nozzle holder 234 provided in mounting head 233, multiple suction nozzles 235 capable of holding component P are detachably provided. Suction nozzle 235 is supported to be rotatable about an axis line parallel to the Z-axis direction (up-down direction of component mounter 20) and to be movable up and down with respect to mounting head 233. Suction nozzle 235 holds component P supplied to component supply position Ps by the pickup, and mounts held component P on positioned circuit board K.

Part camera 24 and board camera 25 are digital imaging devices having imaging elements such as a CCD or a CMOS. Part camera 24 is fixed to a base of component mounter 20 in a state of directing an optical axis in the Z-axis direction, and images component P held by suction nozzle 235 from below. Board camera 25 is fixed to moving table 232 in a state of directing an optical axis in the Z-axis direction, and images circuit board K from above.

Control device 26 is a computer device including CPU, ROM, RAM, and various interfaces as main components, and integrally controls the operation of component mounter 20. Specifically, control device 26 operates component mounter 20 by executing various programs (not illustrated). Accordingly, for example, component mounter 20 performs the mounting operation of component P according to a sequence stored in advance.

### 3. Tape Feeder 30

As illustrated in FIG. 3, tape feeder 30 includes feeder main body 31, drive sprocket 32, manual sprocket 33, tape pressing section 34, and peeling section 35. In addition, tape feeder 30 includes reel holding device 40 which is provided integrally with feeder main body 31 and holds reel R around which component supply tape 50 is wound.

In the present embodiment, as illustrated in FIG. 3, reel holding device 40 is provided integrally with feeder main body 31, that is, the “main body” of reel holding device 40 is provided to be shared with feeder main body 31. However, reel holding device 40 may be provided as a separate body to be accommodated inside feeder main body 31, for example. In this case, reel holding device 40 includes a “main body” that is separate from feeder main body 31.

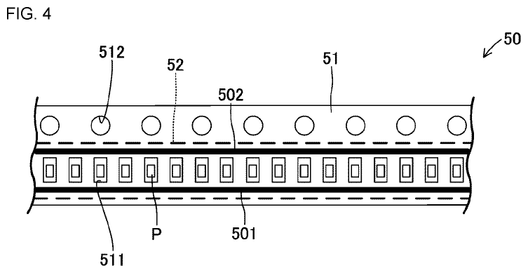

Here, component supply tape 50 wound around reel R will be described. As illustrated in FIG. 4, component supply tape 50 includes base tape 51 and cover tape 52. Base tape 51 is made of a flexible material such as paper or resin. On a first side (lower side in FIG. 4) of base tape 51 in the width direction, multiple cavities 511 capable of accommodating components P are provided at equal intervals along a longitudinal direction (left-right direction in FIG. 4) of base tape 51. On a second side (upper side in FIG. 4) of base tape 51 in the width direction, multiple feed holes 512 are provided at equal intervals along the longitudinal direction of base tape 51. Multiple feed holes 512 mesh with drive sprocket 32 and manual sprocket 33.

Cover tape 52 is formed using a transparent high molecular weight film or the like. As indicated by a broken line in FIG. 4, cover tape 52 covers the upper surface of base tape 51 and prevents component P accommodated in cavity 511 from falling off. Base tape 51 and cover tape 52 are joined to each other at joining portion 501 and joining portion 502 provided on both sides (the first side and the second side) of component supply tape 50 in the width direction with cavity 511 interposed therebetween. Here, joining portion 501 and joining portion 502 are provided on a first side of component supply tape 50 in the width direction with respect to feed hole 512.

Feeder main body 31 is a thin box-shaped member formed of a transparent or non-transparent resin plate, a metal plate, or the like. Although not illustrated, a side surface of feeder main body 31 is provided to be openable and closable, and as illustrated in FIG. 3, drive sprocket 32, manual sprocket 33, tape pressing section 34, peeling section 35, and reel holding device 40 are disposed inside feeder main body 31.

Drive sprocket 32 is a sprocket that can mesh with feed hole 512 provided in base tape 51 of component supply tape 50, and is rotatably provided in feeder main body 31. Motor 321 (for example, a stepping motor or the like) is connected to drive sprocket 32 via multiple gears (not illustrated). Accordingly, drive sprocket 32 is driven by motor 321 to pitch feed component supply tape 50, thereby conveying component P to component supply position Ps.

Here, component supply position Ps, when viewed from a rotational axis direction (X-axis direction) of drive sprocket 32, is provided above a position where drive sprocket 32 is disposed. Accordingly, in tape feeder 30, since an engaging position of component supply tape 50 and drive sprocket 32 can be disposed at a position close to component supply position Ps, tape feeder 30 increases positioning accuracy of component P to be conveyed to component supply position Ps.

Manual sprocket 33 is a sprocket that can mesh with feed hole 512 provided in base tape 51, and is provided between reel holding device 40 and tape pressing section 34 in a conveyance direction of component supply tape 50. Manual sprocket 33 is used when component supply tape 50 drawn out from reel R is conveyed to the engaging position with drive sprocket 32 after new reel R is mounted on reel holding device 40. Therefore, manual sprocket 33 is provided with knob section 331 so that the manual operation by an operator is possible.

Tape pressing section 34 guides component supply tape 50 drawn out from reel R such that component P is conveyed to component supply position Ps. Until component P reaches component supply position Ps, peeling section 35 peels off cover tape 52 from base tape 51 and brings component P accommodated in cavity 511 into a state where component P can be picked up by suction nozzle 235 (refer to FIG. 2).

Here, an operation performed when new reel R is mounted on reel holding device 40 in tape feeder 30 will be briefly described. After mounting new reel R on reel holding device 40, the operator draws out component supply tape 50 from reel R and engages feed hole 512 with manual sprocket 33. Thereafter, the operator rotates manual sprocket 33 by operating knob section 331. Accordingly, component supply tape 50 is conveyed toward the engaging position with drive sprocket 32. Then, by engaging conveyed component supply tape 50 with drive sprocket 32, tape feeder 30 is in a state in which pitch feeding of component supply tape 50 by drive sprocket 32 is possible.

Details of the configuration and operation of tape feeder 30 can be referred to, for example, contents described in WO 2019/229993A1 or the like.

### 4. Reel Holding Device 40

As illustrated in FIG. 3, reel holding device 40 includes reel holder 41 that is integrally provided with feeder main body 31 serving as a “main body” and accommodates reel R. Further, reel holding device 40 includes pressing plate 42 that presses a side surface orthogonal to central axis J1 of reel R accommodated in reel holder 41.

Pressing plate 42 is provided to be openable and closable with respect to feeder main body 31 (main body). Accordingly, as illustrated in FIG. 3, in a closed state in which pressing plate 42 presses reel R, pressing plate 42 covers and presses the side surface of reel R to include central axis J1 of reel R, that is, so that the upper end of pressing plate 42 is above central axis J1 and center pin 45 described later in the Z-axis direction (the vertical direction which is the up-down direction). Further, in an open state in which reel R is not pressed, for example, pressing plate 42 can mount new reel R.

Pressing plate 42 is supported by pair of hinges 43 provided on feeder main body 31 (main body) below in the Z-axis direction (the vertical direction which is the up-down direction), specifically, below central axis J1, and is coupled to feeder main body 31 (main body). Accordingly, pressing plate 42 is disposed below central axis J1 of reel R and is capable of rotating about rotation axis J2 orthogonal to central axis J1. In the present embodiment, rotation axis J2 is provided along the Y-axis direction (front-rear direction). Further, pressing plate 42 is locked in a closed state by lock mechanism 44 provided upward in the Z-axis direction and separated in the Y-axis direction.

Accordingly, pressing plate 42 presses the side surface of reel R by being locked by lock mechanism 44 in the closed state in which pressing plate 42 is rotated about hinge 43. Further, in a state in which the lock by lock mechanism 44 is released, pressing plate 42 rotates about hinge 43 and is in an open state in which pressing plate 42 does not press the side surface of reel R. When pressing plate 42 is in the open state, reel R can be detached from reel holder 41 of reel holding device 40 and reel R can be attached to reel holder 41.

Center pin 45 is provided parallel to central axis J1, more specifically, in the X-axis direction (left-right direction) with respect to reel holder 41 to coincide with central axis J1 of reel R. Center pin 45 rotatably supports reel R by being inserted into central hole R1 provided corresponding to central axis J1 of reel R. Here, center pin 45 is detachably inserted (mounted) into central hole R1 when reel R is exchanged.

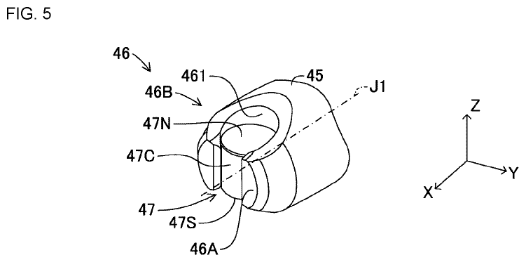

As illustrated in FIG. 5, holding section 46 is formed on an end portion on a distal end side of center pin 45. Holding section 46 includes magnet 47 assembled as described later. Accordingly, holding section 46 attracts and holds pressing plate 42 by the magnetic force in the closed state where pressing plate 42 presses reel R. Here, when pressing plate 42 is formed using a magnetic body such as a metal material, holding section 46 can directly attract and hold pressing plate 42 in the closed state by a magnetic force. Meanwhile, in the case where pressing plate 42 is formed using a non-magnetic body such as resin, for example, a magnetic body is provided in a portion facing holding section 46 in the closed state with respect to pressing plate 42. Accordingly, holding section 46 can hold pressing plate 42 in the closed state by attracting the magnetic body by the magnetic force.

Holding section 46 includes attracting portion 46A corresponding to an end surface of center pin 45 in the direction of the axis line (central axis J1 of reel R), and peripheral portion 46B adjacent to attracting portion 46A. In the present embodiment, peripheral portion 46B corresponds to an outer peripheral surface in a distal end of center pin 45 adjacent to attracting portion 46A.

As illustrated in FIG. 5, magnet 47 of the present embodiment is formed in a cylindrically columnar shape in which magnetic pole 47N or magnetic pole 47S is disposed in each end portion of magnet. The shape of magnet 47 is not limited to the cylindrically columnar shape, and may be another columnar shape, for example, a prismatic shape. In the present embodiment, magnet 47 is inserted into and fixed to assembling hole 461 of holding section 46 provided to coincide with a direction orthogonal to the axis line of center pin 45 (that is, central axis J1 of reel R), specifically, the Z-axis direction (vertical direction which is the up-down direction).

Accordingly, in a state where magnet 47 is assembled to holding section 46 of center pin 45, magnetic pole 47N and magnetic pole 47S are disposed along the Z-axis direction, in other words, along a direction different from central axis J1 of reel R. That is, the disposition direction of magnetic poles 47N and 47S is different from the direction of central axis J1 of reel R. Accordingly, magnetic poles 47N and 47S are disposed on the outer peripheral surface side of center pin 45, that is, in peripheral portion 46B adjacent to attracting portion 46A of holding section 46. Here, magnetic poles 47N and 47S are positions where a magnetic flux density is the largest, and as a result, the largest magnetic force is generated.

In a state where magnet 47 is assembled to holding section 46 of center pin 45, as illustrated in FIG. 5, intermediate portion 47C between magnetic poles 47N and 47S is positioned on the axis line of center pin 45 (central axis J1 of reel R). Therefore, in magnet 47 assembled to holding section 46, intermediate portion 47C having a magnetic force relatively smaller than the magnetic forces of magnetic poles 47N and 47S is positioned in attracting portion 46A. Accordingly, in attracting portion 46A of holding section 46, pressing plate 42 is attracted by the magnetic force of intermediate portion 47C of magnet 47, more specifically, the magnetic force relatively smaller than the magnetic forces of magnetic poles 47N and 47S.

Accordingly, in holding section 46, attracting portion 46A provided on the end surface of center pin 45 in the axis direction attracts pressing plate 42 by the magnetic force of intermediate portion 47C of magnet 47. Further, in holding section 46, magnetic pole 47N and magnetic pole 47S of columnar magnet 47 are disposed in peripheral portion 46B provided on the outer peripheral surface continuous from the end surface of center pin 45. Therefore, at least a part of peripheral portion 46B generates a magnetic force larger than the magnetic force of attracting portion 46A.

Here, as described above, in the work of mounting new reel R on tape feeder 30, for example, peeling or the like occurs in cover tape 52 of component supply tape 50, and component P may be dropped unintentionally into feeder main body 31 (main body). Alternatively, component P attached to the outer surface of cover tape 52 of component supply tape 50 by static electricity may be dropped due to some trigger. In this case, in reel holding device 40 of the present embodiment, dropped component P is preferentially attracted at peripheral portion 46B of holding section 46.

As described above, in magnet 47, magnetic poles 47N and 47S generate the largest magnetic force. In holding section 46, magnetic poles 47N and 47S of magnet 47 are disposed in peripheral portion 46B corresponding to the outer peripheral surface of center pin 45. Accordingly, a magnetic force larger than that of attracting portion 46A is normally generated in peripheral portion 46B.

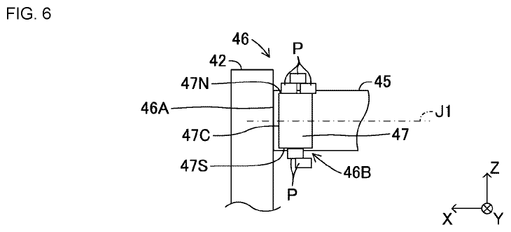

Accordingly, as illustrated in FIG. 6, dropped component P is preferentially attracted at peripheral portion 46B of holding section 46, that is, magnetic pole 47N and magnetic pole 47S that are disposed in peripheral portion 46B and generate a large magnetic force. Therefore, there are many opportunities that dropped component P is attracted at peripheral portion 46B, and as a result, component P is prevented from being attracted at attracting portion 46A of holding section 46 having a relatively small magnetic force compared to peripheral portion 46B.

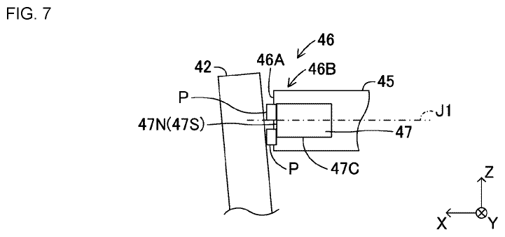

Meanwhile, as illustrated in FIG. 7, when magnet 47 having a cylindrically columnar shape is temporarily assembled such that the axis thereof coincides with the axis line of center pin 45 (central axis J1 of reel R) as in the conventional one, magnetic pole 47N (or magnetic pole 47S) of magnet 47 is disposed in the end portion of center pin 45. In this case, the end portion of center pin 45, that is, attracting portion 46A attracting pressing plate 42 generates a magnetic force larger than that of peripheral portion 46B in which intermediate portion 47C is disposed by magnetic pole 47N (or magnetic pole 47S) of magnet 47. Accordingly, in this case, dropped component P is preferentially attracted at attracting portion 46A of holding section 46.

Here, as illustrated in FIG. 7, in a state where dropped component P is attracted at attracting portion 46A of holding section 46, component P is engaged between attracting portion 46A, that is, the end portion of center pin 45 and pressing plate 42 in the closed state. As a result, when pressing plate 42 is closed, a situation may occur in which pressing plate 42 cannot be properly closed. In a state in which pressing plate 42 is opened more than in the normal state illustrated in FIG. 6, for example, when loader 26 sets tape feeder 30 on which new reel R is mounted in slot 221, tape feeder 30 which is widened in the width direction may interfere with adjacent tape feeder 30, for example.

Meanwhile, as in holding section 46 of the present embodiment illustrated in FIG. 6, in a case where component P that has been dropped is preferentially attracted at peripheral portion 46B of holding section 46, such a possibility is significantly reduced that component P is engaged between attracting portion 46A, that is, the end portion of center pin 45, and pressing plate 42 in the closed state. Therefore, there is a low possibility that pressing plate 42 is open and the width of tape feeder 30 increases, that is, the desired feeder width can be maintained, and as a result, it is possible to prevent interference with the adjacent tape feeder 30 when tape feeder 30 is set in slot 221. Component P attracted by peripheral portion 46B of holding section 46 is removed by an operator, for example, when maintenance is performed on tape feeder 30.

As can be understood from the above description, reel holding device 40 includes pressing plate 42 that shares feeder main body 31 as a main body and is openable and closable with respect to feeder main body 31 to press the side surface orthogonal to central axis J1 of reel R around which component supply tape 50 is wound and which is accommodated in reel holder 41, and holding section 46 that attracts and holds pressing plate 42 by the magnetic force in the closed state in which pressing plate 42 presses reel R, holding section 46 includes attracting portion 46A that attracts pressing plate 42 and peripheral portion 46B adjacent to attracting portion 46A, and the magnetic force larger than the magnetic force of attracting portion 46A is generated in at least a part of peripheral portion 46B.

Accordingly, in reel holding device 40, for example, in a case where component P is dropped from component supply tape 50 in the work of mounting new reel R, component P is preferentially attracted at peripheral portion 46B having a large magnetic force. In other words, it is possible to reduce the possibility (or frequency) that attracting portion 46A adjacent to peripheral portion 46B attracts component P.

Accordingly, in a case where attracting portion 46A of holding section 46 attracts and holds pressing plate 42, the component that has been dropped and attracted is suppressed from being present (being engaged) between attracting portion 46A, that is, the end portion of center pin 45 and pressing plate 42. As a result, in tape feeder 30 in a state in which pressing plate 42 presses reel R, it is possible to prevent the width of tape feeder 30 from becoming wide and to maintain a desired feeder width. Accordingly, for example, when tape feeder 30 is set in slot 221 by loader 26, interference with another adjacent tape feeder 30 can be suppressed, and as a result, favorable setting efficiency can be secured, and damage to tape feeder 30 can be prevented.

Here, prevention of engagement of component P between attracting portion 46A (center pin 45) and pressing plate 42 described above is effectively applied to, for example, a reel loader that automatically sets reel R. In this case, as reel R is automatically set, for example, a process in which the operator checks the state of center pin 45 can be omitted.

### 5. Modification Example

### 5-1. First Modification Example

In the above-described embodiment, the columnar (cylindrically columnar) magnet 47 is assembled to holding section 46 provided on the end portion of center pin 45 such that the disposition direction of magnetic poles 47N and 47S is the vertical direction which is the direction different from central axis J1. Accordingly, magnetic poles 47N and 47S are disposed in peripheral portion 46B of holding section 46, and as a result, the magnetic force of peripheral portion 46B is larger than the magnetic force of attracting portion 46A.

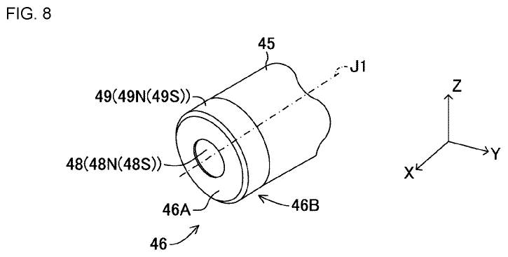

The number of magnets assembled to holding section 46 is not limited to one, and magnets may be assembled to attracting portion 46A and peripheral portion 46B. In the first modification example, as illustrated in FIG. 8, in holding section 46 provided in the end portion of center pin 45, first magnet 48 is disposed in attracting portion 46A, and second magnet 49 is disposed in peripheral portion 46B adjacent to attracting portion 46A.

In this case, second magnet 49 is formed in, for example, an annular shape, and is magnetized so that magnetic pole 49N or magnetic pole 49S exists on each of the outer periphery and the inner periphery. The magnetic force of peripheral portion 46B where second magnet 49 is disposed is set to be larger than the magnetic force of magnetic pole 48N (or magnetic pole 48S) of first magnet 48 assembled to attracting portion 46A. Accordingly, in the first modification example, the same effect as that of the above-described embodiment can be obtained.

### 5-2. Second Modification Example

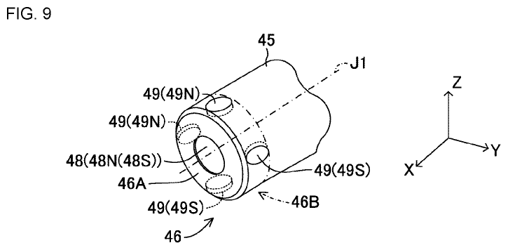

In the first modification example described above, second magnet 49 disposed in peripheral portion 46B has an annular shape. Instead, in the second modification example, as illustrated in FIG. 9, multiple plate-shaped second magnets 49 are disposed in peripheral portion 46B. In this case, second magnets 49 can be disposed, for example, at equal intervals along the circumferential direction of center pin 45. Also in the second modification example, the magnetic force of peripheral portion 46B where multiple second magnets 49 are disposed is set to be larger than the magnetic force of magnetic pole 48N (or magnetic pole 48S) of first magnet 48 assembled to attracting portion 46A. Accordingly, in the second modification example, the same effect as that of the above-described embodiment can be obtained.

### 5-3. Third Modification Example

In the above-described embodiment, reel holding device 40 is incorporated in feeder main body 31 of tape feeder 30. Since reel holding device 40 is incorporated in feeder main body 31, feeder main body 31 is used (shared) as a main body of reel holding device 40. However, as described above, reel holding device 40 is not limited to being provided integrally with tape feeder 30, and may be disposed outside tape feeder 30 to hold one or more reels R like a reel rack, for example. In this case, reel holding device 40 may have a box-shaped or plate-shaped unique “main body”, or may use (share) a main body portion disposed outside a reel rack or the like as in the case of tape feeder 30.

### Reference Signs List

10: production system, 11: automatic conveyance machine, 12: loader, 20: component mounter, 21: board conveyance device, 22: component supply device, 221: slot, 221a: upper stage, 221b: lower stage, 23: component transfer device, 231: head driving device, 232: moving table, 233: mounting head, 234: nozzle holder, 235: suction nozzle, 24: part camera, 25: board camera, 26: control device, 30: tape feeder, 31: feeder main body (main body), 32: drive sprocket, 321: motor, 33: manual sprocket, 331: knob section, 34: tape pressing section, 35: peeling section, 40: reel holding device, 41: reel holder, 42: pressing plate, 43: hinge, 44: lock mechanism, 45: center pin, 46: holding section, 46A: attracting portion, 46B: peripheral portion, 47: magnet, 47N: magnetic pole, 47S: magnetic pole, 47C: intermediate portion, 48: first magnet, 48N: magnetic pole, 48S: magnetic pole, 49: second magnet, 49N: magnetic pole, 49S: magnetic pole, 50: component supply tape, 501: joining portion, 502: joining portion, 51: base tape, 511: cavity, 512: feed hole, 52: cover tape, P: component, Ps: component supply position, R: reel, R1: central hole, J1: central axis, J2: rotation axis

1. A reel holding device comprising:
a main body;
a pressing plate openable and closable with respect to the main body to press a side surface orthogonal to a central axis of a reel around which a component supply tape is wound and which is accommodated in a reel holder; and
a holding section configured to attract and hold the pressing plate by a magnetic force in a closed state in which the pressing plate presses the reel,
wherein the holding section includes an attracting portion configured to attract the pressing plate and a peripheral portion adjacent to the attracting portion, and
a magnetic force larger than a magnetic force of the attracting portion is generated in at least a part of the peripheral portion.

2. The reel holding device according to claim 1, wherein the holding section includes a magnet, and
a magnetic pole of the magnet is disposed in the peripheral portion.

3. The reel holding device according to claim 2, wherein the magnetic pole is disposed along a direction different from a direction of the central axis.

4. The reel holding device according to claim 2, wherein a disposition direction in which the magnetic pole is disposed is a direction orthogonal to a direction of the central axis.

5. The reel holding device according to claim 4, wherein the disposition direction coincides with a vertical direction.

6. The reel holding device according to claim 2, wherein the magnet has a columnar shape in which the magnetic pole is disposed in each end portion.

7. The reel holding device according to claim 2, wherein the attracting portion is disposed at a position different from the magnetic pole of the magnet.

8. The reel holding device according to claim 1, wherein the holding section is provided in a center pin having an axis line along the central axis and inserted into a central hole provided in the reel to rotatably support the reel.

9. The reel holding device according to claim 8, wherein the holding section is provided in an end portion of the center pin.

10. The reel holding device according to claim 8, wherein the center pin is detachably mounted to the central hole of the reel.

11. The reel holding device according to claim 1, wherein the pressing plate opens and closes with respect to the main body by rotating around a rotation axis provided in the main body to be orthogonal to the central axis.

12. The reel holding device according to claim 11, wherein the rotation axis is provided in a hinge configured to rotatably couple the pressing plate to the main body.

13. The reel holding device according to claim 11, wherein the rotation axis is disposed below the central axis in a vertical direction.

14. The reel holding device according to claim 1, wherein the pressing plate presses the side surface of the reel to include the central axis.

15. A tape feeder comprising the reel holding device according to claim 1,
wherein the component supply tape wound around the reel held by the reel holding device is fed.
